(19) United States
(12) Patent Application Publication
(10) Pub. No.: US 2024/0112983 A1
(43) Pub. Date: Apr. 4, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Li WANG, Hsinchu (TW); Chen-Hua YU, Hsinchu (TW); Chuei-Tang WANG, Hsinchu (TW); Shih-Chang KU, Hsinchu (TW)

(73) Assignee: Taiwan Semiconductor Manufacturing Company, Ltd., Hsinchu (TW)

(21) Appl. No.: 18/099,697

(22) Filed: Jan. 20, 2023

Related U.S. Application Data
(60) Provisional application No. 63/411,833, filed on Sep. 30, 2022.

(51) Int. Cl. H01L 23/46; H01L 21/52; H01L 21/56; H01L 23/00; H01L 23/31; H10B 80/00

(52) U.S. Cl. CPC H01L 23/46; H01L 21/52; H01L 21/56; H01L 23/3121; H01L 24/32; H10B 80/00; H01L 23/295; H01L 2224/32245

(57) ABSTRACT

A semiconductor device includes a substrate, a semiconductor component and a heat dissipation component. The semiconductor component is disposed on the substrate. The heat dissipation component is disposed on the substrate and having a cavity, an inlet and an outlet, wherein the inlet and the outlet communicate with the cavity.

### PRIORITY CLAIM AND CROSS-REFERENCE

This application claims the benefit of U.S. provisional application Ser. No. 63/411,833, filed Sep. 30, 2022, the subject matter of which is incorporated herein by reference.

### BACKGROUND

An electronic device generates heat during operation, and the heat negatively affects the operation performance of electronic device. Therefore, how to dissipate heat is one of the goals of those skilled in the art.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a top view of a semiconductor device according to an embodiment of the present disclosure.

FIG. 1B illustrates a schematic diagram of a cross-sectional view of the semiconductor device of FIG. 1 in a direction 1B-1B′.

FIG. 2 illustrates a schematic diagram of a cross-sectional view of the semiconductor device according to another embodiment.

FIG. 3 illustrates a schematic diagram of the semiconductor device of FIG. 1B disposed on a printed circuit board (PCB).

FIG. 4 illustrates a schematic diagram of the semiconductor device of FIG. 2 disposed on the PCB.

FIG. 5 illustrates a schematic diagram of a cross-sectional view of the semiconductor device according to another embodiment of the present disclosure.

FIG. 6 illustrates a schematic diagram of a cross-sectional view of the semiconductor device according to another embodiment of the present disclosure.

FIG. 7 illustrates a schematic diagram of a cross-sectional view of the semiconductor device according to another embodiment of the present disclosure.

FIGS. 8A to 8C illustrate schematic diagrams of manufacturing processes of the semiconductor device of FIG. 1B.

FIGS. 9A to 9D illustrate schematic diagrams of manufacturing processes of the semiconductor device of FIG. 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

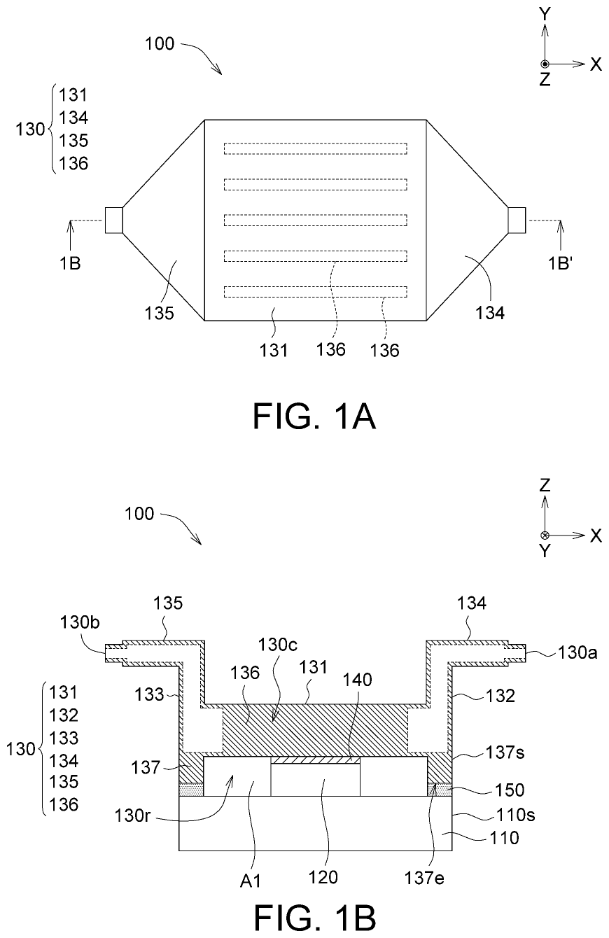

Referring to FIGS. 1A and 1B, FIG. 1A illustrates a schematic diagram of a top view of a semiconductor device 100 according to an embodiment of the present disclosure, and FIG. 1B illustrates a schematic diagram of a cross-sectional view of the semiconductor device 100 of FIG. 1 in a direction 1B-1B′.

As illustrated in FIGS. 1A and 1B, the semiconductor device 100 includes a substrate 110, at least one semiconductor component 120, a heat dissipation component 130, a thermal interface material (TIM) 140 and an adhesive layer 150. The semiconductor component 120 is disposed on the substrate 110. The heat dissipation component 130 is disposed on the substrate 110 and has a cavity 130c, an inlet 130a and an outlet 130b, wherein the inlet 130a and the outlet 130b communicate with the cavity 130c. As a result, the heat dissipation component 130 may dissipate heat from the semiconductor component 120.

When the semiconductor device 100 operates, heat dissipation fluid (for example, gas, air, liquid, etc.) may flow toward the outlet 130b from the inlet 130a and carry heat from the semiconductor component 120 out of the semiconductor device 100.

The substrate 110 may be formed of a material including, for example, organic material, silicon, ceramic, metal, etc. The substrate 110 is, for example, a single-layered substrate or a multi-layered substrate.

The semiconductor component 120 is, for example, a SoC (System on Chip), a Dynamic Random Access Memory (DRAM), a HBM (High Bandwidth Memory), etc.

As illustrated in FIGS. 1A and 1B, the heat dissipation component 130 includes a main body 131, a first extension portion 132, a second extension portion 133, a first flank 134, a second flank 135, a plurality of heat dissipation fins 136 and connection portion 137. The first extension portion 132 is connected with a side of the main body 131 and extends upwards (for example, in +Z-axis, or toward a direction away from the substrate 110). The second extension portion 133 is connected with another side of the main body 131 and extends upwards (for example, in +Z-axis, or toward a direction away from the substrate 110). The first flank 134 is connected with the first extension portion 132 and extends outwards (for example, in +X-axis). The second flank 135 is connected with the second extension portion 133 and extends outwards (for example, in −X-axis). The heat dissipation component 130 is hollow component. Furthermore, the cavity 132c is formed within the main body 131, the first extension portion 132, the second extension portion 133, the first flank 134 and the second flank 135, exposes the inlet 130a from the first flank 134 and exposes the outlet 130b from the second flank 135. The heat dissipation fins 136 may increase the heat dissipation area. The heat dissipation fins 136 are disposed within the cavity 310r and extend in X-axis.

As illustrated in FIG. 1B, the connection portion 137 is connected with the main body 131 and extends downwards (for example, in −Z-axis, or toward the substrate 110). Viewed from the top of FIG. 1B, the heat dissipation component 130 may be, for example, a closed-ring structure surrounding the semiconductor component 120. In another embodiment, the heat dissipation component 130 may be, for example, an open-ring structure.

In an embodiment, at least two of the main body 131, the first extension portion 132, the second extension portion 133, the first flank 134, the second flank 135, the heat dissipation fins 136 and the connection portion 137 may be integrated into one piece. Furthermore, at least one portion of the heat dissipation component 130 may be shaped from a single, continuous piece of material. In another embodiment, at least two of the main body 131, the first extension portion 132, the second extension portion 133, the first flank 134, the second flank 135, the heat dissipation fins 136 and the connection portion 137 may be formed individually, and then combine to each other by using, for example, adhering, welding, engaging, screwing, etc. In an embodiment, the heat dissipation component 130 is formed by using, for example, machining, stamping or a combination thereof. In addition, the heat dissipation component 130 may be formed of a material including, for example, metal, such as gold, silver, copper, iron, aluminum or a combination thereof.

As illustrated in FIG. 1B, the heat dissipation component 130 has a terminal surface 137e and a recess 130r, the recess 130r is recessed with respect to the terminal surface 137e for receiving the semiconductor component 120.

As illustrated in FIG. 1B, the heat dissipation component 130 has a first lateral surface 137s, the substrate 110 has a second lateral surface 110s, and the first lateral surface 137s and the second lateral surface 110s may be flush with each other. In another embodiment, the first lateral surface 137s may be recessed with respect to the second lateral surface 110s. In other embodiment, the first lateral surface 137s may protrude with respect to the second lateral surface 110s.

As illustrated in FIG. 1B, the thermal interface material 140 is disposed between the semiconductor component 120 and the heat dissipation component 130. For example, the thermal interface material 140 may directly connect the semiconductor component 120 and the heat dissipation component 130. The thermal interface material 140 may increase the combination between the semiconductor component 120 and the heat dissipation component 130 and/or increase the heat transfer between the semiconductor component 120 and the heat dissipation component 130. In addition, the thermal interface material 140 is formed of a material including, for example, grease.

As illustrated in FIG. 1B, in the present embodiment, the heat dissipation component 130 and the semiconductor component 120 are connected by only insulation material, for example, the thermal interface material 140. In other words, there is no electrically conductive material disposed between the heat dissipation component 130 and the semiconductor component 120.

As illustrated in FIG. 1B, the adhesive layer 150 is disposed between the substrate 110 and the heat dissipation component 130. Furthermore, the adhesive layer 150 directly or indirectly connects the substrate 110 and the connection portion 137 of the heat dissipation component 130. The adhesive layer 150 may increase the combination between the substrate 110 and the heat dissipation component 130. In another embodiment, the adhesive layer 150 may be thermal interface material. Viewed from the top of FIG. 1B, the adhesive layer 150 may be, for example, a closed-ring structure surrounding the semiconductor component 120. In another embodiment, the adhesive layer 150 may be, for example, an open-ring structure.

As illustrated in FIG. 1B, there is a continuous air layer A1 within space among the substrate 110, the heat dissipation component 130 and the semiconductor component 120. In another embodiment, the semiconductor device 100 may further include a package body filling up the space to cover the semiconductor component 120, wherein such package body may include, for example, a Novolac-based resin, an epoxy-based resin, a silicone-based resin, or another suitable encapsulant. Suitable fillers also can be included, such as powdered SiO2. The package body may be applied using any of a number of molding techniques, such as compression molding, injection molding, or transfer molding. In another embodiment, the package body may be under-fill material.

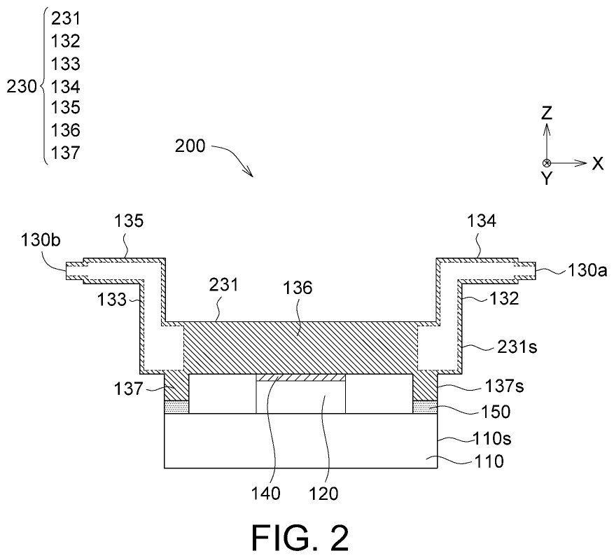

Referring to FIG. 2, FIG. 2 illustrates a schematic diagram of a cross-sectional view of the semiconductor device 200 according to another embodiment of the present disclosure.

The semiconductor device 200 includes the substrate 110, at least one semiconductor component 120, a heat dissipation component 230, the thermal interface material 140 and the adhesive layer 150. The semiconductor component 120 is disposed on the substrate 110. The heat dissipation component 230 is disposed on the substrate 110 and has the cavity 130c, the inlet 130a and the outlet 130b, wherein the inlet 130a and the outlet 130b communicate with the cavity 130c. As a result, the heat dissipation component 230 may dissipate heat from the semiconductor component 120.

The semiconductor device 200 includes the features the same as or similar to that of the semiconductor device 100 except that, for example, the heat dissipation component 230 includes the structure different from that of the heat dissipation component 130.

As illustrated in FIG. 2, the heat dissipation component 230 includes a main body 231, the first extension portion 132, the second extension portion 133, the first flank 134, the second flank 135, a plurality of the heat dissipation fins 136 and the connection portion 137. The main body 231 includes the features the same as or similar to that of the main body 131 except that, for example, the main body 231 is wider (in X-axis and/or Y-axis) than the main body 131. Furthermore, the connection portion 137 has the first lateral surface 137s, the main body 231 has a third lateral surface 231s, the third lateral surface 231 protrudes with respect to the first lateral surface 137s and the second lateral surface 110s. The wider main body 231 may increase cooling performance. In an embodiment, the length of the main body 231 in X-axis may increase by 30%, more or less than that of the main body 131.

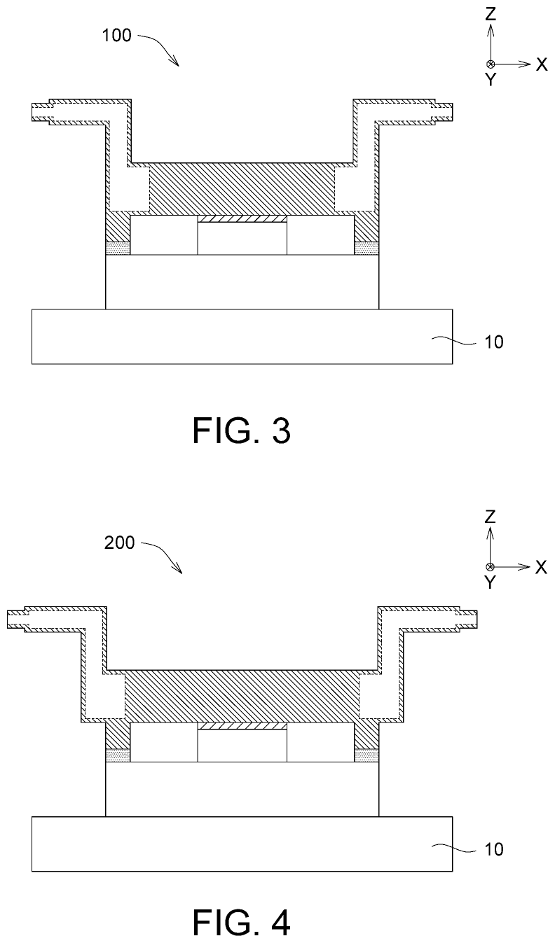

Referring to FIG. 3, FIG. 3 illustrates a schematic diagram of the semiconductor device 100 of FIG. 1B disposed on a printed circuit board (PCB) 10. The semiconductor device 100 of FIG. 1B may be disposed on the PCB 10. The PCB 10 is, for example, a main board in an electronic device.

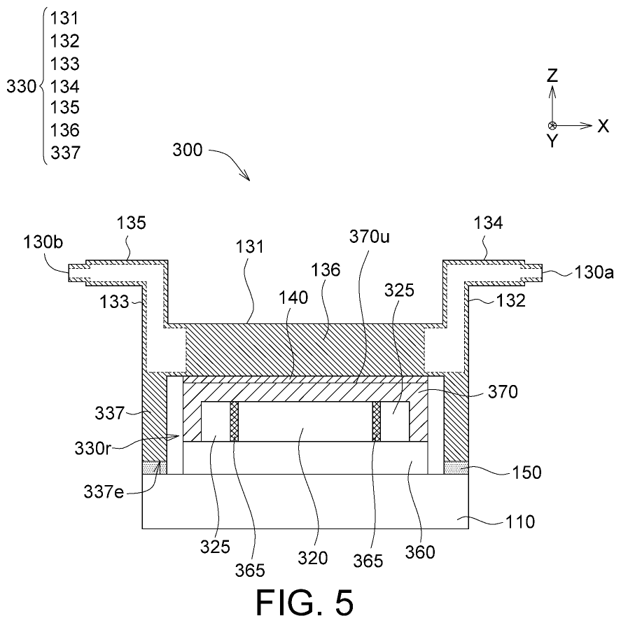

Referring to FIG. 4, FIG. 4 illustrates a schematic diagram of the semiconductor device 200 of FIG. 2 disposed on the PCB 10. The semiconductor device 200 of FIG. 2 may be disposed on the PCB 10.

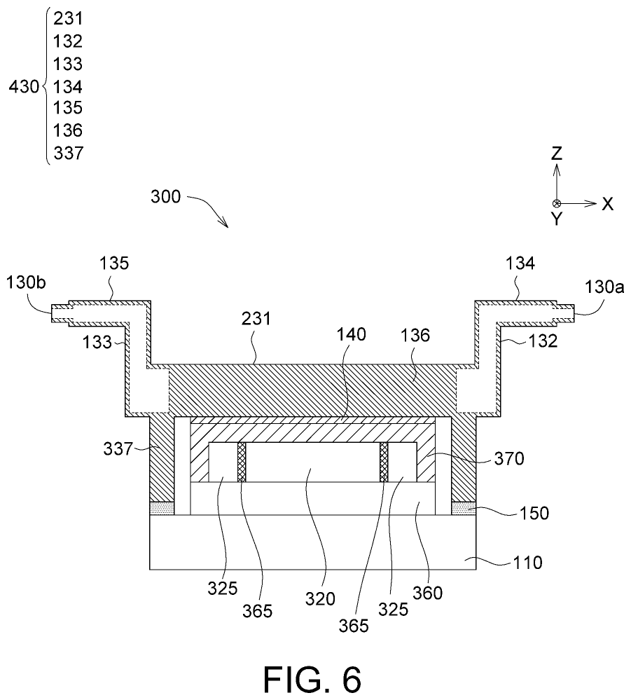

Referring to FIG. 5, FIG. 5 illustrates a schematic diagram of a cross-sectional view of the semiconductor device 300 according to another embodiment of the present disclosure. The semiconductor device 300 includes the substrate 110, a plurality of semiconductor components 320 and 325, the heat dissipation component 330, the thermal interface material 140, the adhesive layer 150, an interposer 360, an under-fill 365 and a package body 370. The interposer 360 is disposed on the substrate 110. The semiconductor components 320 and 325 are disposed on the interposer 360. The heat dissipation component 330 is disposed on the substrate 110 and has the cavity 130c, the inlet 130a and the outlet 130b, wherein the inlet 130a and the outlet 130b communicate with the cavity 130c. As a result, the heat dissipation component 330 may dissipate heat from the semiconductor components 320 and 325.

In the present embodiment, the semiconductor component 320 is, for example, SoC, while the semiconductor component 325 is, for example, DRAM, HBM, etc.

As illustrated in FIG. 5, the heat dissipation component 330 includes the main body 131, the first extension portion 132, the second extension portion 133, the first flank 134, the second flank 135, the heat dissipation fins 136 and the connection portion 337. The heat dissipation component 330 has a terminal surface 337e and a recess 330r, the recess 330r is recessed with respect to the terminal surface 337e for receiving the semiconductor components 320 and 325 and the interposer 360. The connection portion 337 may have a longer length in Z-axis than the connection portion 137 of FIG. 1B for increasing the volume of the recess 130r to receive more components.

As illustrated in FIG. 5, the interposer 360 is, for example, a single-layered substrate or a multi-layered substrate. The interposer 360 may be applied to a Chip-On-Wafer-On-Substrate (CoWoS) or an Integrated Fan-Out (InFO) structure. The interposer 360 may be formed of a material including, for example, organic material, silicon, ceramic, metal or a combination thereof. The material of the interposer 360 may depend on the structure of the substrate 110.

As illustrated in FIG. 5, the under-fill 365 may fill up an interval between the adjacent two of the semiconductor components 320 and 325.

As illustrated in FIG. 5, the package body 370 is formed on the interposer 360 and encapsulates the semiconductor components 320 and 325. The package body 370 may include, for example, a Novolac-based resin, an epoxy-based resin, a silicone-based resin, or another suitable encapsulant. Suitable fillers also can be included, such as powdered SiO2. The package body 370 may be applied using any of a number of molding techniques, such as compression molding, injection molding, or transfer molding. In addition, the package body 370 has a top surface 370u. The thermal interface material 140 is disposed on the top surface 370u of the package body 370. The top surface 370u is, for example, a plane, such that the thermal interface material 140 may contact with the entire of the top surface 370u for increasing the heat transfer between the top surface 370u of the package body 370 and the heat dissipation component 330 and/or the combination to the top surface 370u of the package body 370.

In another embodiment, the semiconductor device 300 may be disposed on the PCB 10 of FIG. 3.

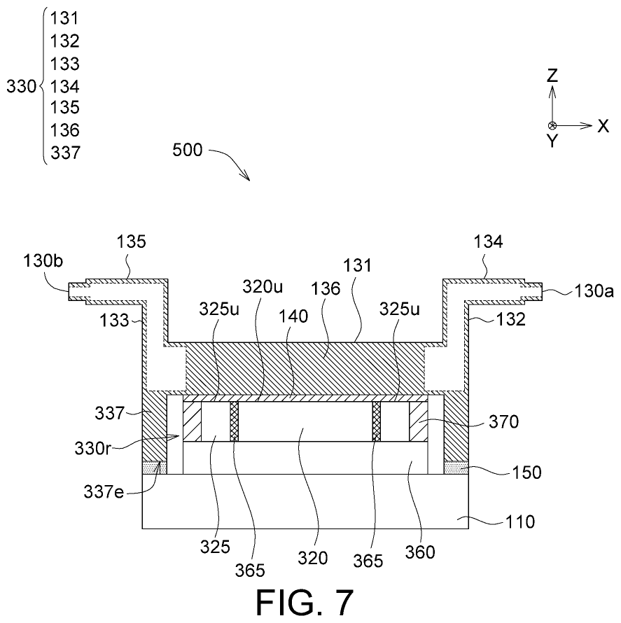

Referring to FIG. 6, FIG. 6 illustrates a schematic diagram of a cross-sectional view of the semiconductor device 400 according to another embodiment of the present disclosure. The semiconductor device 400 includes the substrate 110, a plurality of semiconductor components 320 and 325, the heat dissipation component 430, the thermal interface material 140, the adhesive layer 150, the interposer 360, the under-fill 365 and the package body 370. The interposer 360 is disposed on the substrate 110. The semiconductor components 320 and 325 are disposed on the interposer 360. The heat dissipation component 430 is disposed on the substrate 110 and has the cavity 130c, the inlet 130a and the outlet 130b, wherein the inlet 130a and the outlet 130b communicate with the cavity 130c. As a result, the heat dissipation component 430 may dissipate heat from the semiconductor components 320 and 325.

As illustrated in FIG. 6, the heat dissipation component 430 includes the main body 231, the first extension portion 132, the second extension portion 133, the first flank 134, the second flank 135, the heat dissipation fins 136 and the connection portion 337. The heat dissipation component 430 includes the features the same as or similar to that of the heat dissipation component 330 except that, for example, the main body 231 of the heat dissipation component 430 is different from the main body 131 of the heat dissipation component 330.

In another embodiment, the semiconductor device 400 may be disposed on the PCB 10 of FIG. 4.

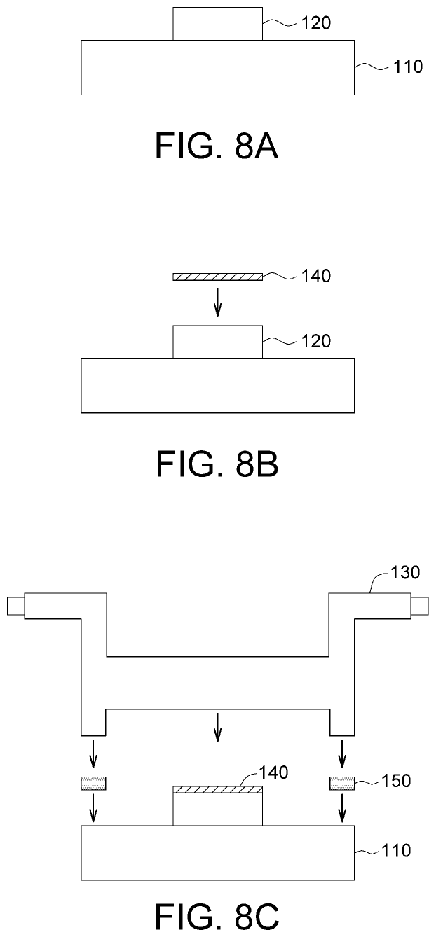

Referring to FIG. 7, FIG. 7 illustrates a schematic diagram of a cross-sectional view of the semiconductor device 500 according to another embodiment of the present disclosure. The semiconductor device 500 includes the substrate 110, a plurality of semiconductor components 320 and 325, the heat dissipation component 330, the thermal interface material 140, the adhesive layer 150, the interposer 360, the under-fill 365 and the package body 370. The interposer 360 is disposed on the substrate 110. The semiconductor components 320 and 325 are disposed on the interposer 360. The heat dissipation component 330 is disposed on the substrate 110 and has the cavity 130c, the inlet 130a and the outlet 130b, wherein the inlet 130a and the outlet 130b communicate with the cavity 130c. As a result, the heat dissipation component 330 may dissipate heat from the semiconductor components 320 and 325.

In another embodiment, the heat dissipation component 330 of the semiconductor device 500 of FIG. 7 may be replaced by the heat dissipation component 430 of the semiconductor device 400 of FIG. 6.

In the present embodiment, the semiconductor component 320 is, for example, SoC, while the semiconductor component 325 is, for example, DRAM, HBM, etc. Each semiconductor component 320 has a top surface 320u, and each semiconductor component 325 has a top surface 325u, wherein the top surface 320u and 325u are flush with each other. The thermal interface material 140 is disposed on the top surfaces 320u and 325u. Due to the top surfaces of the semiconductor components being flush with each other, the thermal interface material 140 may contact the entire of each of the top surfaces 320u and 325u for increasing the heat transfer between all semiconductor components and the heat dissipation component 330.

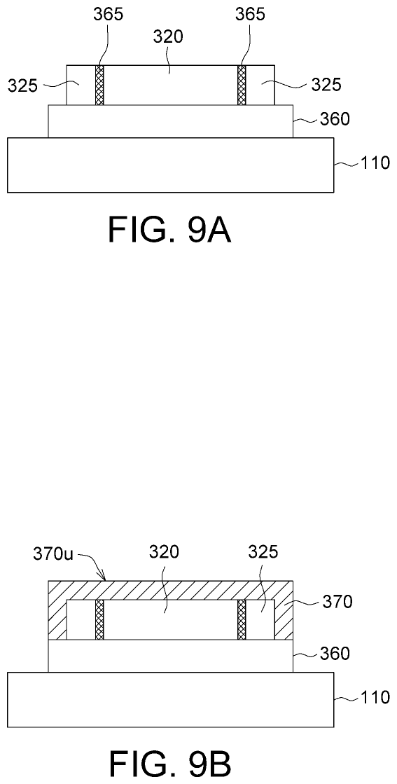

FIGS. 8A to 8C illustrate schematic diagrams of manufacturing processes of the semiconductor device 100 of FIG. 1B.

As illustrated in FIG. 8A, at least one semiconductor component 120 is disposed on the substrate 110 by using, for example, SMT (Surface Mount Technology).

As illustrated in FIG. 8B, the thermal interface material 140 is disposed on the semiconductor component 120.

As illustrated in FIG. 8C, the heat dissipation component 130 is disposed on the substrate 110 through the adhesive layer 150. The adhesive layer 150 is disposed between the substrate 110 and the heat dissipation component 130. For example, the adhesive layer 150 connects the substrate 110 and the heat dissipation component 130. In addition, the thermal interface material 140 is disposed between the semiconductor component 120 and the heat dissipation component 130. For example, the thermal interface material 140 directly connects the semiconductor component 120 and the heat dissipation component 130. So far, the semiconductor device 100 of FIG. 1B is formed or completed.

In another embodiment, the semiconductor device 100 formed in FIG. 8C may be disposed on the PCB 10, as illustrated in FIG. 3.

The semiconductor device 200 of FIG. 2 may be formed by using the processes the same as or similar to that of the semiconductor device 100, and the similarities will be not repeated here.

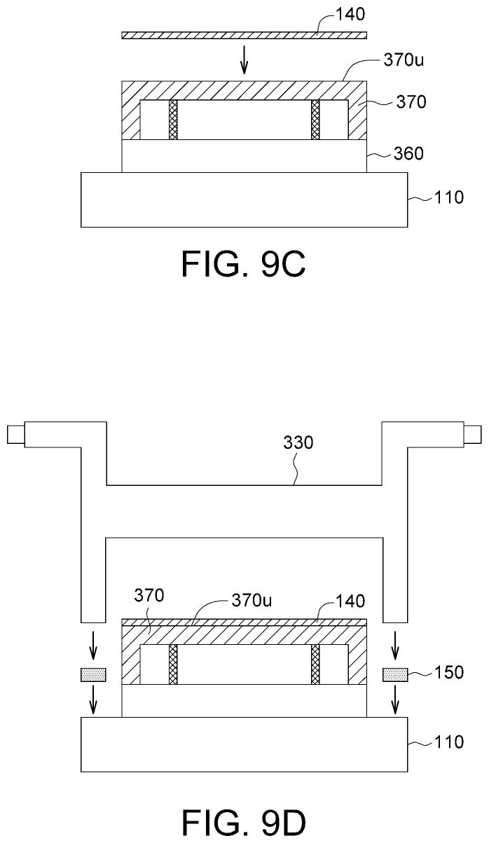

FIGS. 9A to 9D illustrate schematic diagrams of manufacturing processes of the semiconductor device 200 of FIG. 2.

As illustrated in FIG. 9A, the semiconductor components 320 and 325 are disposed on the substrate 110 through the interposer 360.

In an embodiment, the interposer 360 is disposed on the substrate 110. Then, at least one semiconductor component 320 and at least one semiconductor component 325 are disposed on the interposer 360. Then, the under-fill 365 is formed within an interval between the adjacent two of the semiconductor components 320 and 325.

In another embodiment, at least one semiconductor component 320 and at least one semiconductor component 325 are disposed on the interposer 360 in advance. Then, the under-fill 365 is formed within an interval between the adjacent two of the semiconductor components 320 and 325. Then, such pre-assembled structure of the interposer 360 and the semiconductor components is disposed on the substrate 110.

As illustrated in FIG. 9B, the package body 370 encapsulating the semiconductor components 320 and 325 is formed on the interposer 360. The package body 370 may be formed by using any of a number of molding techniques, such as compression molding, injection molding, or transfer molding. The package body 370 has the top surface 370u.

As illustrated in FIG. 9C, the thermal interface material 140 is disposed on the package body 370. Furthermore, the thermal interface material 140 is disposed on the top surface 370u of the package body 370. The top surface 370u is, for example, a plane, such that the thermal interface material 140 may contact with the entire of the top surface 370u for increasing the heat transfer between the top surface 370u of the package body 370 and the subsequent heat dissipation component 330 and/or the combination to the top surface 370u of the package body 370.

As illustrated in FIG. 9D, the heat dissipation component 330 is disposed on the substrate 110 through the adhesive layer 150. The adhesive layer 150 is disposed between the substrate 110 and the heat dissipation component 330. For example, the adhesive layer 150 may directly or indirectly connect the substrate 110 and the heat dissipation component 330. In addition, the thermal interface material 140 is disposed between the package body 370 and the heat dissipation component 330. For example, the thermal interface material 140 directly connects the package body 370 and the heat dissipation component 330. So far, the semiconductor device 300 of FIG. 3 is formed or completed.

The semiconductor device 400 of FIG. 6 may be formed by using the processes the same as or similar to that of the semiconductor device 300, and the similarities will not be repeated here.

The semiconductor device 500 of FIG. 7 may be formed by using the processes the same as or similar to that of the semiconductor device 300 except that, for example, the package body 370 exposes the semiconductor components 320 and 325, wherein the top surface 320u (illustrated in FIG. 7) of each semiconductor component 320 and the top surface 325u (illustrated in FIG. 7) of each semiconductor component 325 are flush with each other.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device including a substrate, a heat dissipation component disposed on the substrate and a semiconductor component disposed between the substrate and the heat dissipation component is provided, wherein the heat dissipation component includes a cavity, an inlet and an outlet which communicate with the cavity. Accordingly, the heat dissipation component may dissipate heat from the semiconductor component through a heat dissipation fluid within the cavity.

Example embodiment 1: a semiconductor device includes a substrate, a semiconductor component and a heat dissipation component. The semiconductor component is disposed on the substrate. The heat dissipation component is disposed on the substrate and having a cavity, an inlet and an outlet, wherein the inlet and the outlet communicate with the cavity.

Example embodiment 2 based on Example embodiment 1: the semiconductor device further includes a thermal interface material (TIM) disposed between the semiconductor component and the heat dissipation component.

Example embodiment 3 based on Example embodiment 1: the thermal interface material connects the semiconductor component with the heat dissipation component.

Example embodiment 4 based on Example embodiment 1: the semiconductor device further includes an adhesive layer disposed between the substrate and the heat dissipation component.

Example embodiment 5 based on Example embodiment 4: the adhesive layer connects the substrate and the heat dissipation component.

Example embodiment 6 based on Example embodiment 1: the heat dissipation component has a terminal surface and a recess, the recess is recessed with respect to the terminal surface for receiving the semiconductor component.

Example embodiment 7 based on Example embodiment 1: there is an air layer among the substrate, the heat dissipation component and the semiconductor component.

Example embodiment 8 based on Example embodiment 1: the heat dissipation component has a first lateral surface, the substrate has a second lateral surface, and the first lateral surface and the second lateral surface are flush with each other.

Example embodiment 9 based on Example embodiment 1: the heat dissipation component has a first lateral surface, the substrate has a second lateral surface, and the first lateral surface is recessed with respect to the second lateral surface.

Example embodiment 10 based on Example embodiment 1: the heat dissipation component has a first lateral surface, the substrate has a second lateral surface, and the first lateral surface protrudes with respect to the second lateral surface.

Example embodiment 11 based on Example embodiment 10: the heat dissipation component includes a connection portion and a main body connected with the connection portion and includes the cavity, the inlet and the outlet, the connection portion has the first lateral surface, the main body has a third lateral surface, and the third lateral surface protrudes with respect to the first lateral surface.

Example embodiment 12 based on Example embodiment 1: the heat dissipation component is shaped from a single, continuous piece of material.

Example embodiment 13 based on Example embodiment 1: the semiconductor device further includes a plurality of the semiconductor components each having a top surface, wherein the top surfaces of the semiconductor components are flush with each other; and a thermal interface material disposed on the top surfaces of the semiconductor components.

Example embodiment 14 based on Example embodiment 1: the heat dissipation component and the semiconductor component are connected by only insulation material.

Example embodiment 15: a semiconductor device includes a substrate, an interposer disposed on the substrate, a plurality of semiconductor components disposed on the interposer, and a heat dissipation component disposed on the substrate and having a cavity, an inlet and an outlet, wherein the inlet and the outlet communicate with the cavity.

Example embodiment 16 based on Example embodiment 15: each semiconductor component has a top surface, and the top surfaces of the semiconductor components are flush with each other.

Example embodiment 17: a manufacturing method of a semiconductor device includes disposing a semiconductor component on a substrate; and disposing a heat dissipation component on the substrate, wherein the heat dissipation component has a cavity, an inlet and an outlet, and the inlet and the outlet communicate with the cavity.

Example embodiment 18 based on Example embodiment 17: the manufacturing method further includes disposing an interposer on the substrate; and disposing the semiconductor component on the substrate through the interposer.

Example embodiment 19 based on Example embodiment 17: the manufacturing method further includes disposing the heat dissipation component on the substrate through an adhesive layer.

Example embodiment 20 based on Example embodiment 17: the manufacturing method further includes disposing a plurality of the semiconductor components on the substrate, wherein each semiconductor component has a top surface, and the top surfaces of the semiconductor components are flush with each other; and disposing a thermal interface material on the top surfaces of the semiconductor components.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a semiconductor component disposed on the substrate; and
a heat dissipation component disposed on the substrate and having a cavity, an inlet and an outlet, wherein the inlet and the outlet communicate with the cavity.

2. The semiconductor device as claimed in claim 1, further comprising:
a thermal interface material (TIM) disposed between the semiconductor component and the heat dissipation component.

3. The semiconductor device as claimed in claim 1, wherein the thermal interface material connects the semiconductor component with the heat dissipation component.

4. The semiconductor device as claimed in claim 1, further comprising:
an adhesive layer disposed between the substrate and the heat dissipation component.

5. The semiconductor device as claimed in claim 4, wherein the adhesive layer connects the substrate and the heat dissipation component.

6. The semiconductor device as claimed in claim 1, wherein the heat dissipation component has a terminal surface and a recess, the recess is recessed with respect to the terminal surface for receiving the semiconductor component.

7. The semiconductor device as claimed in claim 1, wherein there is an air layer among the substrate, the heat dissipation component and the semiconductor component.

8. The semiconductor device as claimed in claim 1, wherein the heat dissipation component has a first lateral surface, the substrate has a second lateral surface, and the first lateral surface and the second lateral surface are flush with each other.

9. The semiconductor device as claimed in claim 1, wherein the heat dissipation component has a first lateral surface, the substrate has a second lateral surface, and the first lateral surface is recessed with respect to the second lateral surface.

10. The semiconductor device as claimed in claim 1, wherein the heat dissipation component has a first lateral surface, the substrate has a second lateral surface, and the first lateral surface protrudes with respect to the second lateral surface.

11. The semiconductor device as claimed in claim 10, wherein the heat dissipation component comprises a connection portion and a main body connected with the connection portion and comprising the cavity, the inlet and the outlet, the connection portion has the first lateral surface, the main body has a third lateral surface, and the third lateral surface protrudes with respect to the first lateral surface.

12. The semiconductor device as claimed in claim 1, wherein the heat dissipation component is shaped from a single, continuous piece of material.

13. The semiconductor device as claimed in claim 1, further comprising:
a plurality of the semiconductor components each having a top surface, wherein the top surfaces of the semiconductor components are flush with each other; and
a thermal interface material disposed on the top surfaces of the semiconductor components.

14. The semiconductor device as claimed in claim 1, wherein the heat dissipation component and the semiconductor component are connected by only insulation material.

15. A semiconductor device, comprising:
a substrate;
an interposer disposed on the substrate;
a plurality of semiconductor components disposed on the interposer; and
a heat dissipation component disposed on the substrate and having a cavity, an inlet and an outlet, wherein the inlet and the outlet communicate with the cavity.

16. The semiconductor device as claimed in claim 15, wherein each semiconductor component has a top surface, and the top surfaces of the semiconductor components are flush with each other.

17. A manufacturing method of a semiconductor device, comprising:
disposing a semiconductor component on a substrate; and
disposing a heat dissipation component on the substrate, wherein the heat dissipation component has a cavity, an inlet and an outlet, and the inlet and the outlet communicate with the cavity.

18. The manufacturing method as claimed in claim 17, further comprising:
disposing an interposer on the substrate; and
disposing the semiconductor component on the substrate through the interposer.

19. The manufacturing method as claimed in claim 17, further comprising:
disposing the heat dissipation component on the substrate through an adhesive layer.

20. The manufacturing method as claimed in claim 17, further comprising:
disposing a plurality of the semiconductor components on the substrate, wherein each semiconductor component has a top surface, and the top surfaces of the semiconductor components are flush with each other; and
disposing a thermal interface material on the top surfaces of the semiconductor components.
